(19) United States
(12) Patent Application Publication
(10) Pub. No.: US 2015/0115437 A1
(43) Pub. Date: Apr. 30, 2015

(54) UNIVERSAL ENCAPSULATION SUBSTRATE, ENCAPSULATION STRUCTURE AND ENCAPSULATION METHOD

(71) Applicants: Jian Cai, Beijing (CN); Yuanyuan Pu, Beijing (CN); Qian Wang, Beijing (CN); Han Guo, Beijing (CN)

(72) Inventors: Jian Cai, Beijing (CN); Yuanyuan Pu, Beijing (CN); Qian Wang, Beijing (CN); Han Guo, Beijing (CN)

(21) Appl. No.: 14/365,100

(22) PCT Filed: Dec. 23, 2011
(86) PCT No.: PCT/CN2011/084495

§ 371 Date: Nov. 24, 2014

(30) Foreign Application Priority Data
Dec. 12, 2011 (CN) 201110412962.4

(51) Int. Cl. H01L 23/498; H01L 23/00

(52) U.S. Cl. CPC H01L 23/49827; H01L 23/49816; H01L 23/49833; H01L 24/81; H01L 2924/01047; H01L 2924/01013; H01L 2924/01079
USPC 257/737; 438/125

(57) ABSTRACT

A universal packaging substrate, comprising a first substrate (102) and a silicon interposer (103), wherein, a plurality of bumps (106) are formed between the upper surface of the first substrate (102) and the lower surface of the silicon interposer (103) and electrically connect the upper surface of the first substrate (102) and the lower surface of the silicon interposer (103), and a plurality of wire bonding pads are formed on the upper surface of the silicon interposer (103) and are electrically connected to the bumps (106) respectively via silicon through holes (105). Also disclosed are a packaging structure provided with the packaging substrate and an packaging method. The substrate is suitable for small batch integrated circuit products, providing low cost and short cycle for packaging.

### FIELD OF THE INVENTION

The present invention relates to semiconductor packaging field, in particular to a universal packaging substrate, a packaging, and a packaging method.

### BACKGROUND OF THE INVENTION

Ball Grid Array (BAG) packaging technique is an advanced high-performance area array packaging technique developed since 1990's. BGA packaging technique has been applied rapidly and widely in light-weight, small-size, and high-performance devices owing to its advantages, such as a large number of I/O ports, big pitch, high reliability, short pins, and high coplanarity, etc., and has become a mature high-density packaging technique. FIG. 1 is a schematic diagram of existing flip-chip BGA packaging.

However, at present, BGA packaging is in a stage in which chip design and packaging design are separate from each other; consequently, the substrate design is chip-specific, i.e., a chip developed separately has to be provided with a specifically designed packaging substrate; therefore, packaging research and development has to be carried out in the early stage for samples and products; as a result, a great deal of cost is required, and the packaging cycle has to be prolonged owing to substrate design and manufacture. For large-batch chip packaging, since the cost of packaging design in the early stage can be apportioned into the product cost, it will not have a severe impact; however, for small-batch chip packaging, cost will be further increased if new packaging design is required, since the product scale is not large and the cost is already high. Therefore, it is desirable that a novel packaging design should be created to meet the requirements of small-batch chip packaging.

### SUMMARY OF THE INVENTION

In view of the drawbacks in verification of small-batch integrated circuit products and samples in the prior art, such as high packaging cost and long packaging cycle, etc., the present invention provides a universal packaging substrate, a packaging structure, and a packaging method, to overcome the drawbacks.

The present invention provides a universal packaging substrate, comprising a first substrate and a silicon interposer; a plurality of bumps are formed between the upper surface of the first substrate and the lower surface of the silicon insertion layer and electrically connect the upper surface of the first substrate and the lower surface of the silicon interposer; a plurality of wire bonding pads are formed on the upper surface of the silicon interposer and are electrically connected to the bumps respectively via silicon through holes.

The present invention also provides a packaging structure, comprising the universal packaging substrate described above and at least one chip, wherein, the chip is on the upper surface of the silicon interposer of the universal packaging substrate, and the bonding pads of the chip are electrically connected to the wire bonding pads formed on the upper surface of the silicon interposer respectively by wire bonding.

The present invention also provides a method for packaging chips using the universal packaging substrate described above, comprising:

bonding at least one chip to the upper surface of the silicon insertion layer of the universal packaging substrate;

electrically connecting the bonding pads of the chip to the wire bonding pads formed on the upper surface of the silicon interposer by wire bonding;

packaging the chip by plastic packaging after wire bonding;

mounting balls on the lower surface of the first substrate, to lead out electrical signals from the chip.

In the universal packaging substrate and packaging structure according to the present invention, since the wire bonding pads on the upper surface of the silicon interposer are electrically connected to the bumps on the lower surface of the silicon interposer through the silicon through holes in the silicon interposer and the bonding pads of the chip are electrically connected to the wire bonding pads on the upper surface of the silicon interposer by wire bonding, different chip designs can be integrated by means of the silicon interposer into flip chips that have the same specifications, so that a universal packaging substrate provided in the present invention is applicable to the packaging of chips that are of different types and in different sizes; thus, the packaging cost is decreased, and the packaging cycle is shortened. In addition, the universal packaging substrate and packaging structure according to the present invention can increases the spacing between the bumps on the substrate and enlarge the bumps; moreover, since the bumps can be connected to any bonding pad on the chip by wire bonding, the way of connection can be more flexible, and MCM module packaging can be implemented.

### DESCRIPTION OF THE DRAWINGS

FIG. 1 is a sectional view of the BGA packaging structure in the prior art;

FIG. 2 is a sectional view of the universal packaging substrate according to the present invention;

FIG. 3 is a sectional view of the packaging structure according to the present invention;

FIG. 4 is another sectional view of the packaging structure according to the present invention;

FIG. 5 is another sectional view of the packaging structure according to the present invention;

FIG. 6 is another sectional view of the packaging structure according to the present invention; and

FIG. 7 is a flow chart of chip packaging using the universal packaging substrate according to the present invention.

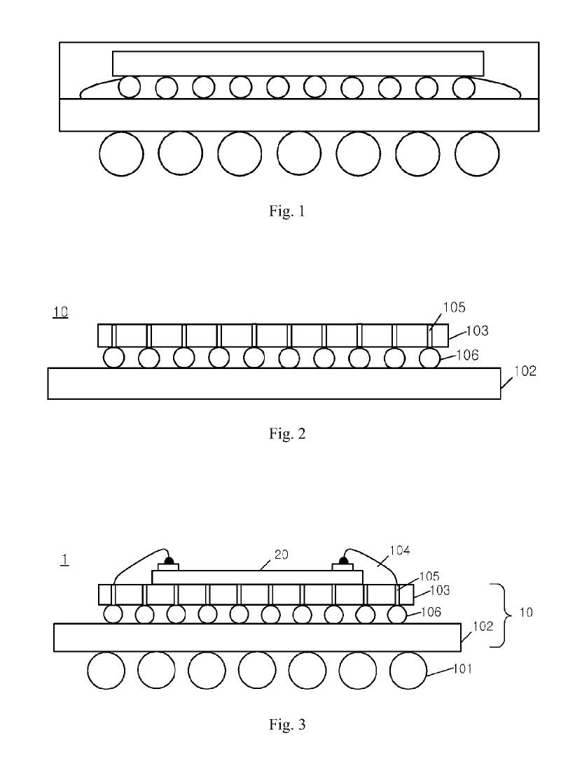

### DETAILED DESCRIPTION OF EMBODIMENTS

Hereafter the universal packaging substrate, packaging structure, and packaging method according to the present invention will be detailed, with reference to the accompanying drawings.

As shown in FIG. 2, the universal packaging substrate 10 according to the present invention comprises a first substrate 102 and a silicon interposer 103; a plurality of bumps 106 are formed between the upper surface of the first substrate 102 and the lower surface of the silicon interposer 103 and electrically connect the same; a plurality of wire bonding pads are formed on the upper surface of the silicon interposer 103 and are electrically connected to the bumps 106 respectively via silicon through holes 105.

Wherein, the first substrate 102 may be an organic substrate, silicon substrate, or ceramic substrate, and the design of the first substrate 102, such as structure, number of layers, and internal interconnection structure, etc., may be similar to the design of BGA packaging substrates in the prior art; hence, the first substrate will not be further detailed any more herein.

In addition, the wire bonding pads formed on the upper surface of the silicon interposer 103 may be made of aluminum, copper, or gold, etc., and their manufacturing process is well known by those skilled in the art; therefore, the wire bonding pads will not be detailed any more herein; moreover, the material of the wire bonding pads can vary, depending on material used for wire bonding.

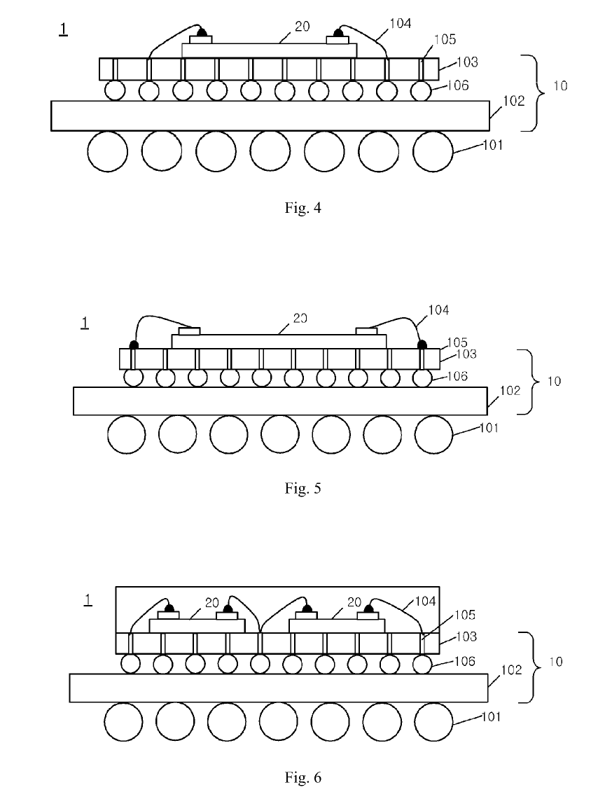

FIG. 3 is a sectional view of the packaging structure 1 according to the present invention, wherein, the packaging structure 1 comprises at least one chip 20 and a universal packaging substrate 10 provided according to the present invention. The packaging substrate 10 is designed to carry at least one chip 20, which is arranged on the upper surface of a silicon interposer 103 of the universal packaging substrate 10 according to the present invention; in addition, the bonding pads of the chip 20 are electrically connected to the wire bonding pads formed on the upper surface of the silicon interposer 103 respectively by wire bonding.

It should be noted that the label 101 in FIG. 3-6 represents solder balls, which are designed to lead out electrical signals from the packaged chip 20 and implement electrical connections between the final packaged assembly with other electronic components.

In a preferred embodiment of the present invention, the bonding pads of the chip 20 are connected to the wire bonding pads on the universal packaging substrate 10 according to the present invention by one or more of gold wire bonding, copper wire bonding, or aluminum wire bonding.

In another preferred embodiment of the present invention, the bonding pads of the chip 20 are connected to the corresponding wire bonding pads on the universal packaging substrate according to the present invention by forward bonding and/or reverse bonding. FIG. 3 and FIG. 4 illustrate the forward bonding, while FIG. 5 illustrates the reverse bonding. Since the forward bonding and reverse bonding are known by those skilled in the art, they will not be further detailed any more herein.

The structure of the universal packaging substrate 10 in FIG. 3 is identical to the structure of the universal packaging substrate 10 in FIG. 4, but the design of the chip 20 in FIG. 3 is different from the design of the chip 20 in FIG. 2. Nevertheless, the chips 20 in different designs shown in FIG. 3 and FIG. 4 can be connected to the universal packaging substrate 10 in the present invention by wire bonding, without redesigning the structure of the universal packaging substrate 10 in the present invention; thus, the packaging cost can be reduced, and the manufacturing time can be shortened.

In another preferred embodiment of the present invention, multi-chip module (MCM) packaging can be implemented using the universal packaging substrate 10 according to the present invention, as shown in FIG. 6.

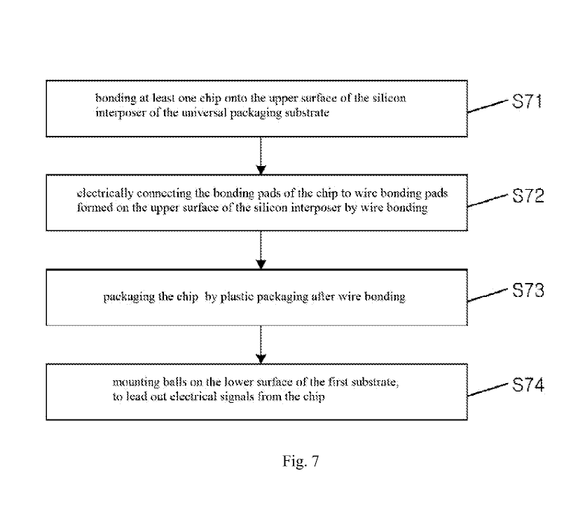

FIG. 7 shows a packaging method that utilizes the universal packaging substrate 10 according to the present invention, comprising:

S71: bonding at least one chip 20 onto the upper surface of the silicon interposer 103 of the universal packaging substrate 20;

wherein, the chip 20 can be bonded onto the upper surface of the silicon interposer 103 by means of silver paste or any other bonding agent;

S72: electrically connecting the bonding pads of the chip 20 to wire bonding pads formed on the upper surface of the silicon interposer 103 by wire bonding;

wherein, the bonding pads of the chip 20 may be connected to the corresponding wire bonding pads on the universal packaging substrate 10 by one or more of gold wire bonding, copper wire bonding, or aluminum wire bonding, and the wire bonding may be forward bonding and/or reverse bonding;

S73: packaging the chip 20 by plastic packaging after wire bonding;

S74: mounting balls on the lower surface of the first substrate 102, to lead out electrical signals from the chip 20.

As described above, MCM packaging can be implemented using the universal packaging substrate according to the present invention. When MCM packaging is implemented, a plurality of chips can be die-stacked or bonded on the upper surface of the silicon interposer (i.e., without die-stack).

Though the present invention is detailed above in some preferred embodiments of the present invention, it should be appreciated that various modifications and variations can be made to the present invention, without departing from the spirit and scope of the present invention.

1. A universal packaging substrate, comprising a first substrate and a silicon interposer, wherein a plurality of bumps are formed between the upper surface of the first substrate and the lower surface of the silicon interposer and electrically connect the upper surface of the first substrate and the lower surface of the silicon interposer, and a plurality of wire bonding pads are formed on the upper surface of the silicon interposer and are electrically connected to the bumps respectively via silicon through holes.

2. The universal packaging substrate according to claim 1, wherein, the first substrate is an organic substrate, silicon substrate, or ceramic substrate.

3. A packaging structure, comprising:
a universal packaging substrate as comprising a first substrate and a silicon interposer, wherein a plurality of bumps are formed between the upper surface of the first substrate and the lower surface of the silicon interposer and electrically connected to the upper surface of the first substrate and the lower surface of the silicon interposer, and a plurality of wire bonding pads are formed on the upper surface of the silicon interposer and are electrically connected to the bumps respectively via silicon through holes; and
at least one chip, wherein the chip is on the upper surface of the silicon interposer of the universal packaging substrate, and bonding pads of the chip are electrically connected to the wire bonding pads formed on the upper surface of the silicon interposer respectively by wire bonding.

4. The packaging structure according to claim 3, wherein, the bonding pads of the chip are connected to the corresponding wire bonding pads by gold wire bonding and/or copper wire bonding and/or aluminum wire bonding.

5. The packaging structure according to claim 3, wherein, the bonding pads of the chip are connected to the corresponding wire bonding pads by forward bonding and/or reverse bonding.

6. A method for packaging chips using a universal packaging substrate comprising a first substrate and a silicon interposer, wherein a plurality of bumps are formed between the upper surface of the first substrate and the lower surface of the silicon interposer and electrically connect the upper surface of the first substrate and the lower surface of the silicon interposer, and a plurality of wire bonding pads are formed on the upper surface of the silicon interposer and are electrically connected to the bumps respectively via silicon through holes, wherein the method comprises:
bonding at least one chip onto the upper surface of the silicon interposer of the universal packaging substrate;
electrically connecting the bonding pads of the chip to the wire bonding pads formed on the upper surface of the silicon interposer by wire bonding;
packaging the chip by plastic packaging after the wire bonding; and
mounting balls on the lower surface of the first substrate to lead out electrical signals from the chip.

7. The method according to claim 6, wherein, the chip is bonded onto the upper surface of the silicon interposer by means of silver paste.

8. The method according to claim 6, wherein, the bonding pads of the chip are connected to the corresponding wire bonding pads on the universal packaging substrate by gold wire bonding and/or copper wire bonding and/or aluminum wire bonding.

9. The method according to claim 6, wherein, the bonding pads of the chip are connected to the corresponding wire bonding pads on the universal packaging substrate by forward bonding and/or reverse bonding.
